(19) United States
(12) Patent Application Publication
(10) Pub. No.: US 2011/0249381 A1
(43) Pub. Date: Oct. 13, 2011

(54) MINI IMPLANT

(76) Inventor: Michael Diebold, Berlin (DE)

(21) Appl. No.: 13/052,149

(22) Filed: Mar. 21, 2011

Related U.S. Application Data
(60) Provisional application No. 61/323,371, filed on Apr. 13, 2010.

(51) Int. Cl. H05K 5/00; G01R 19/00; G06K 19/077

(52) U.S. Cl. 361/679.01; 235/492; 324/76.11

(57) ABSTRACT

The invention relates to a mini implant, including a housing made of biocompatible, electrically insulating plastic and an electric circuit including electronic components, at least some of which are connected to electrically conductive leads having biocompatible surfaces. One or more of the leads is disposed on inner surfaces of the housing, so that the housing effectively acts as a printed circuit board.

### CROSS-REFERENCE TO RELATED APPLICATIONS

This application claims priority under 35 USC §119(e) to U.S. Provisional Patent Application 61/323,371 filed 13 Apr. 2010, the entirety of which is incorporated by reference herein.

### FIELD OF THE INVENTION

The invention relates to a mini implant which can be easily inserted into the body of a patient due to the small dimensions thereof.

### BACKGROUND

Mini implants for identification purposes often include a simple RFID (radio frequency identification) circuit, typically having a coil and a ferrite core and associated electronics. The RFID circuit is often encased in glass to form a biocompatible housing.

### SUMMARY

The invention seeks to increase the integration density of mini implants to implement more complex functionalities and/or to configure the mini implants even smaller. The goal is to achieve RFID implants with integrated sensors that are (for example) the size of a rice grain (e.g., 5-10 mm in length, with a diameter of one-half to one-third this size). Such smaller size can be achieved by a mini implant having a housing made of biocompatible, electrically insulating plastic material, and an electric circuit containing suitable electronic components. In addition, the mini implant has electrically conductive leads for electrically connecting the electronic components to each other. At least some of these leads are disposed on inner surfaces of the housing and have a biocompatible surface. At least some of the electronic components are disposed inside the housing and connected to the leads. Because the leads are disposed directly on surfaces of the housing, the housing can essentially function as a “printed circuit board” for the electronic circuit situated in the housing. In this way, a greater number of components can be accommodated in a smaller space in order to reduce the overall size of the implant, or to allow more complex functionality to be implemented while maintaining the same size.

In a preferred version of the invention, the biocompatible, electrically insulating plastic of the housing is a liquid crystal polymer (LCP). Liquid crystal polymers are biocompatible and electrically insulating, and therefore suited particularly well for a hermetically sealed housing of an implant according to the invention.

The leads are preferably made of gold or another biocompatible conductor, or are at least coated on the outsides thereof with gold, so that the leads are also biocompatible (at least on the outsides thereof).

The electric circuit preferably forms at least one RFID unit. Additionally or alternatively, the circuit can be designed to serve as a control unit or sensor circuit. In this case, it is advantageous if at least one of the leads extends to the outside of the housing, for example, to serve as a sensor electrode.

In the foregoing or other versions of the mini implant, the housing has cavities which are open (or closed) to the outside of the housing, and these cavities may contain chemical active ingredients. The active ingredients may have a therapeutic effect, or might be consumed as they assist with sensor functions performed by the electric circuit (e.g., they may react with the chemistry of the body in which the mini implant is situated, with the reaction then being sensed by the electric circuit to generate a sensor signal). These cavities can be designed such that are initially closed to thereafter open only after the implant has been implanted, such as by the action of heat or by biodegradation, or by another chemical or physical effect controlled by time or other factors. For this purpose, the cavities are preferably closed with a layer made of biodegradable material, and/or a material which dissolves or otherwise degrades under the influence of heat.

In addition, or as an alternative, the housing of the mini implant preferably has an elongated shape with two longitudinal ends and includes at least one cap on one (or both) of the longitudinal ends. This cap is preferably designed as a membrane and allows, for example, the metered release of the active ingredient, and/or the penetration of body fluid so that the body fluid may interact with a sensor arrangement disposed behind the cap.

Sensor arrangements, or other arrangements wherein at least some of the electric components are to establish temporary or sustained contact with body fluid, can also utilize one or more exterior electric components connected to electric components inside the housing via one or more fluid-tight feedthroughs extending through the housing.

The mini implant preferably includes at least one fluid-tight chamber wherein electric components requiring protection from outside influences (e.g., to the surrounding body environment) are located.

In another preferred version of the invention, the housing of the mini implant is coated with a biocompatible material, wherein the material is preferably selected such that a desired degree of tissue ingrowth into the implant occurs after implantation.

Instead of a housing made of a thermoplastic resin, such as liquid crystal polymer, the housing may be produced from other materials, e.g., a thermoset material (in which case subsequent heat-induced deformation of the housing may be difficult or impossible).

### BRIEF DESCRIPTION OF THE DRAWINGS

An exemplary version of the invention will now be described in more detail with reference to the figures, which show:

FIG. 1: an external view of the mini implant;

FIG. 2: a longitudinal sectional view of the mini implant of FIG. 1; and

FIG. 3: longitudinal section of another version of the mini implant.

### DETAILED DESCRIPTION OF EXEMPLARY VERSIONS OF THE INVENTION

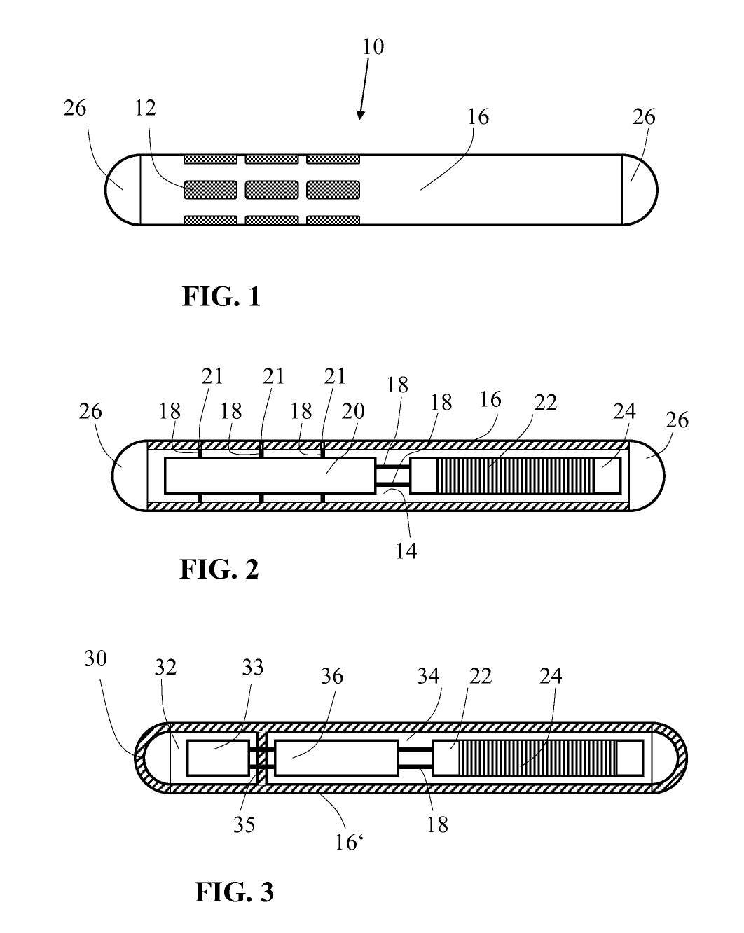

FIG. 1 shows an exemplary mini implant 10 having sensors 12 situated about the outside of a housing 16 of the mini implant 10. The sensors 12 can be simple electrically conductive surfaces, for example, or other forms of sensors, e.g., electrochemical sensors.

FIG. 2 shows a longitudinal sectional view of the mini implant 10 of FIG. 1. It illustrates that leads 18, which connect to an electric circuit 20 (e.g., a microchip), are disposed on the inner surface 14 of the housing 16 of the mini implant 10. In addition, the leads 18 communicate with the sensors 12 on the outside of the housing 16 of the implant 10 by way of appropriate hermetically sealed feedthroughs 21, which are not shown in detail.

In this exemplary mini implant 10, the leads 18 are made of gold and are therefore biocompatible. As an alternative, the leads 18 could be formed by copper leads having a gold coating, for example.

The housing 16 of the mini implant 10 is preferably made of a biocompatible, electrically non-conductive thermoplastic resin, with liquid crystal polymer (LCP) being particularly preferred.

Preferably, a coil 22 having a ferrite core 24 is disposed in the housing 16 of the implant 10 and can be used to feed energy into the mini implant 10 by way of induction. The coil 22 can also be used to transmit identification and other data.

The housing 16 is closed by end caps 26 at the two longitudinal ends thereof. These end caps 26 may be hermetically sealed to the housing 16. As an alternative, one or both of the end caps can be designed as a membrane pervious to body fluid, as exemplified by the left end cap 30 illustrated in FIG. 3. This cap closes a cavity 32 in the housing 16′ wherein the cavity 32 serves as an analysis chamber containing a sensor 33, for example, a pressure sensor, electrochemical sensor, and/or another type of sensor. The cavity 32 is separated in a gas- and fluid-tight manner from a hermetically sealed chamber 34 in the housing 16′ by a separating wall having a feedthrough 35. The chamber 34 contains a microelectronic system 36 designed as an electronic control system, and also contains the coil 22 having the ferrite core 24 (as discussed above with respect to FIG. 2).

Components of the housing 16 or 16′ can be produced using an injection molding method, for example, and can be connected to each other in sealed relationship by (for example) ultrasonic welding after installation of the components of the implant 10.

The housing can also include other chambers, cavities, and components so that more complex mini implants can also be implemented in accordance with the foregoing concepts.

The versions of the invention describe above are presented for purposes of illustration only, and it will be apparent to those skilled in the art that numerous modifications and variations of the foregoing versions are possible in light of the concepts discussed in this document. Other alternate versions may include some or all of the features disclosed herein, and/or may include additional features. Therefore, the invention is not limited to the versions described above, and it encompasses all different versions that fall literally or equivalently within the scope of the claims below.

What is claimed is:

1. A mini implant including:
a. a housing made of biocompatible, electrically insulating plastic,
b. an electric circuit including electronic components situated inside the housing, and
c. electrically conductive leads having a biocompatible surface, wherein at least some of the leads are:
(1) disposed on inner surfaces of the housing, and
(2) connected to the electronic components.

2. The mini implant of claim 1 wherein the electric circuit includes an RFID unit.

3. The mini implant of claim 1 wherein the electric circuit includes a controller.

4. The mini implant of claim 1 wherein at least some of the leads extend to an outer surface of the housing.

5. The mini implant of claim 1 wherein the implant includes an electric or electrochemical sensor connected to the electric circuit.

6. The mini implant of claim 5 wherein the electric or electrochemical sensor is:
a. situated on an outer surface of the implant, and
b. electrically connected to the circuit by way of a fluid-tight feedthrough through which at least one of the leads extends.

7. The mini implant of claim 5 wherein the electric or electrochemical sensor is:
a. situated within a chamber defined within the implant, and
b. electrically connected to the circuit by way of a fluid-tight feedthrough through which at least one of the leads extends.

8. The mini implant of claim 1 wherein the housing has at least one cavity defined therein, the cavity being closed to the outside of the housing but being configured to open after implantation of the mini implant within a body.

9. The mini implant of claim 8 wherein the cavity is closed by at least one layer of biodegradable material, the biodegradable material being configured to decompose after implantation of the mini implant within a body so that the cavity opens after implantation.

10. The mini implant of claim 8 wherein the cavity is closed by at least one layer of material meltable at a temperature at, or within five degrees (celsius) of, the standard temperature of a human body.

11. The mini implant of claim 8 wherein the cavity is at least partially filled with an active chemical ingredient.

12. The mini implant of claim 1 wherein the plastic of the housing is a liquid crystal polymer.

13. The mini implant of claim 1 wherein the housing has a length extending between opposing longitudinal ends.

14. The mini implant of claim 13 wherein at least one of the longitudinal ends has a membrane thereon bounding a chamber defined within the interior of the housing.

15. The mini implant of claim 13 wherein the housing has a diameter sized between 25%-35% of the length of the housing.

16. The mini implant of claim 15 wherein the length of the housing is 5-10 mm.

17. The mini implant of claim 1 wherein the electric circuit includes a telemetry unit configured to wirelessly send data from the implant.

18. The mini implant of claim 1 wherein the housing carries a biocompatible coating on the outside thereof which promotes tissue ingrowth.

19. A mini implant including:
a. an elongated housing formed of electrically insulating biocompatible material, the housing having:
(1) a length extending between opposing longitudinal ends;
(2) an exterior surface;
(3) an interior situated within the exterior surface, the interior including a chamber bounded by an inner surface;
b. electric components situated within the interior of the housing;
c. an electrically conductive lead:
(1) affixed to the inner surface of the chamber, and
(2) connected to the electric components.

20. A mini implant including:
a. a housing formed of electrically insulating biocompatible material, the housing having:
(1) an exterior surface;
(2) an interior situated within the exterior surface, the interior including a chamber bounded by an inner surface;
b. electric components situated within the interior of the housing, the electric components including a coil;
c. an electrically conductive lead:
(1) connected to the electric components,
(2) affixed to the inner surface of the chamber, and
(3) extending to the exterior surface of the housing via a fluid-tight feedthrough.
